(19) United States
(12) Patent Application Publication
(10) Pub. No.: US 2012/0307187 A1
(43) Pub. Date: Dec. 6, 2012

(54) METHOD FOR PRODUCING LIQUID CRYSTAL DISPLAY PANEL, AND LIQUID CRYSTAL DISPLAY PANEL

(76) Inventor: Shigeki Tanaka, Osaka-shi (JP)

(21) Appl. No.: 13/577,986

(22) PCT Filed: Dec. 6, 2010
(86) PCT No.: PCT/JP2010/071797

§ 371 Date: Aug. 9, 2012

(30) Foreign Application Priority Data
Feb. 9, 2010 (JP) 2010-026276

(51) Int. Cl. H01L 33/08; G02F 1/1337

(52) U.S. Cl. 349/123; 438/30; 257/E33.012

(57) ABSTRACT

A method for producing a liquid crystal display panel (1) including a pair of transparent substrates (3, 4) opposed to each other, a liquid crystal layer (2) that contains liquid crystal molecules (21) and is sandwiched between the substrates, and optical alignment films (36, 46) for aligning the liquid crystal molecules, the films being formed on inner surfaces of the substrates and subjected to an alignment treatment through light irradiation, includes the step of bonding the substrates to each other while sandwiching the layer therebetween, where the optical alignment films that are yet to be subjected to the treatment are each formed on the substrates, and the step of subjecting the optical alignment films to the treatment where the light (51) is projected from an outer surface of either one of the bonded substrates toward an outer surface of the other substrate to obliquely traverse the optical alignment films.

### TECHNICAL FIELD

The present invention relates to a liquid crystal display panel including optical alignment films, and a method for producing the same.

### BACKGROUND ART

An optical alignment film disclosed in NPL 1 and other literatures is known as an optical alignment film used for a liquid crystal display panel. Being irradiated with light such as ultraviolet light from a specific direction, the optical alignment film develops alignment regulation power in accordance with the irradiation direction of the light. The optical alignment film controls a direction of tilt (a pretilt direction) of liquid crystal molecules by using its alignment regulation power.

Because the optical alignment film can develop the alignment regulation power only by being irradiated with the light as described above, it is unnecessary to rub a surface of the optical alignment film (unnecessary to subject the surface to a rubbing processing), while the conventional alignment film needs to rub. For this reason, the optical alignment film is free from problems such as occurrence of static electricity and adherence of foreign particles, which the conventional alignment film carries, and is favorably used in recent years.

A liquid crystal display panel including optical alignment films of this kind is disclosed in PTL 1. Disclosed in PTL 1 is the liquid crystal display panel including a pair of transparent substrates (TFT substrate and CF substrate), where the transparent substrates are opposed to each other while sandwiching a liquid crystal layer therebetween. In the liquid crystal display panel, the optical alignment films are each disposed on inner surfaces of the transparent substrates. The optical alignment films are subjected to alignment treatments such that the directions of alignment regulation power of the optical alignment films are different from each other. The alignment treatments are performed before the liquid crystal display panel is assembled. That is, the optical alignment films on the transparent substrates are individually irradiated with light before the transparent substrates are bonded so as to be opposed to each other while sandwiching the liquid crystal layer therebetween.

In addition, a liquid crystal display panel including optical alignment films is disclosed in PTL 2. Disclosed in PTL 2 is the liquid crystal display panel including a pair of transparent substrates, where the transparent substrates are opposed to each other while sandwiching a liquid crystal layer therebetween, and the optical alignment films are each disposed on inner surfaces of the transparent substrates as shown in FIG. 8 of PTL 2. The optical alignment film disposed on the one transparent substrate (TFT substrate) of the liquid crystal display panel is subjected to an alignment treatment after the transparent substrates are bonded. To be specific, the one transparent substrate (TFT substrate), on which the optical alignment film is disposed, is irradiated with light from its outer surface toward its inner surface. Meanwhile, the optical alignment film disposed on the other transparent substrate (CF substrate) is irradiated with light and subjected to an alignment treatment in advance before the liquid crystal display panel is assembled.

### CITATION LIST

### Patent Literature

PTL 1: JP2008-145700A

PTL 2: JP2009-282366A

### Non Patent Literature

NPL 1: Yoneda-syuppan, “Optical Alignment of Liquid Crystals”, Editor ICHIMURA, Kunihiro, Mar. 7, 2007

### SUMMARY OF INVENTION

### Technical Problem

In the conventional methods for producing the liquid crystal display panels, the optical alignment films on the transparent substrates need to be individually irradiated with light and subjected to the alignment treatments as disclosed in PTLs 1 and 2. For this reason, irradiation angles and irradiation amounts of the light vary between the optical alignment films, which could result in variation between the directions and sizes of alignment regulation power that the optical alignment films develop. When the transparent substrates including the above-described optical alignment films are bonded while sandwiching the liquid crystal layer therebetween, liquid crystal molecules in the liquid crystal layer have a pretilt angle (pretilt direction) that is deviated from an intended angle. The deviation in the pretilt angle causes a problem of exacerbating the display properties of the liquid crystal display panel.

In addition, in the conventional methods for producing the liquid crystal display panels, because the optical alignment films need to be individually subjected to the alignment treatments as described above, there arises a problem of reduced production efficiency.

In order to overcome the problems described above, preferred embodiments of the present invention provide a method for efficiently producing a liquid crystal display panel, in which liquid crystal molecules are prevented from having a deviated pretilt direction in forming optical alignment films arranged to align the liquid crystal molecules on opposed surfaces of a pair of transparent substrates that are opposed to each other while sandwiching a liquid crystal layer containing the liquid crystal molecules therebetween.

### Solution to Problem

A method for producing a liquid crystal display panel of the present invention, and a liquid crystal display panel produced in the method of the present invention are as follows.

<1> A method for producing a liquid crystal display panel including a pair of transparent substrates being opposed to each other, a liquid crystal layer that contains liquid crystal molecules and is sandwiched between the transparent substrates, and optical alignment films for aligning the liquid crystal molecules, the optical alignment films being formed on inner surfaces of the transparent substrates and subjected to an alignment treatment through light irradiation, the method including the step of bonding the transparent substrates to each other while sandwiching the liquid crystal layer therebetween, where the optical alignment films that are yet to be subjected to the alignment treatment are each formed on the transparent substrates, and the step of subjecting the optical alignment films to the alignment treatment where the light is projected from an outer surface of either one of the bonded transparent substrates toward an outer surface of the other transparent substrate.

<2> The method according to <1>, wherein in the alignment treatment step, an angle of the light that is projected onto the outer surface of the either one transparent substrate is thirty to sixty degrees.

<3> The method according to <1> or <2>, wherein in the alignment treatment step, the light is projected in a plurality of directions from the outer surface of the either one transparent substrate toward the outer surface of the other transparent substrate via exposure masks each corresponding to the directions, the exposure masks being disposed above the outer surface of the either one transparent substrate, and thereby the optical alignment films are domain-divided by the light projected in the plurality of directions.

<4> The method according to any one of <1> to <3>, wherein one of the paired transparent substrates defines a thin film transistor substrate including a plurality of thin film transistors arranged in a matrix, and the other transparent substrate defines a color filter substrate including a plurality of color filters arranged in a matrix, and in the alignment treatment step, the light is projected from an outer surface of the thin film transistor substrate toward an outer surface of the color filter substrate.

<5> The method according to any one of <1> to <4>, wherein the method further includes the step of each attaching polarizing plates to the outer surfaces of the paired transparent substrates, where polarization axes of the polarizing plates are tilted at about forty-five degrees to an orientation of the projected light.

<6> A method for producing a liquid crystal display panel including a pair of transparent substrates being opposed to each other, a liquid crystal layer that contains liquid crystal molecules and is sandwiched between the transparent substrates, and optical alignment films for aligning the liquid crystal molecules, the optical alignment films being formed on inner surfaces of the transparent substrates and subjected to alignment treatments through light irradiation, the method including the step of bonding the transparent substrates to each other while sandwiching the liquid crystal layer therebetween, where the optical alignment films that are yet to be subjected to the alignment treatments are each formed on the transparent substrates, and the step of subjecting the optical alignment films to the alignment treatments where the light is projected from an outer surface of one of the bonded transparent substrates toward an outer surface of the other transparent substrate, and the light is projected from the outer surface of the other transparent substrate toward the outer surface of the one transparent substrate, the light projected from the outer surface of the one transparent substrate toward the outer surface of the other transparent substrate being parallel and opposite in direction to the light projected from the outer surface of the other transparent substrate toward the outer surface of the one transparent substrate .

<7> The method according to <6>, wherein in the alignment treatment step, angles of the light and the light that are parallel and opposite in direction to each other and projected onto the outer surfaces of the paired transparent substrates are thirty to sixty degrees.

<8> The method according to <6> or <7>, wherein in the alignment treatment step, the light and the light that are parallel and opposite in direction to each other are projected in a plurality of directions from the outer surface of the one transparent substrate toward the outer surface of the other transparent substrate and from the outer surface of the other transparent substrate toward the outer surface of the one transparent substrate via exposure masks corresponding to the directions, the exposure masks being disposed above the outer surface of the one transparent substrate and above the outer surface of the other transparent substrate, and thereby the optical alignment films are domain-divided by the light and the light projected in the plurality of directions.

<9> The method according to any one of <6> to <8>, wherein the method further includes the step of each attaching polarizing plates to the outer surfaces of the paired transparent substrates, where polarization axes of the polarizing plates are tilted at about 45 degrees to orientations of the projected light and light.

<10> The method according to any one of <1> to <9>, wherein the liquid crystal display panel defines a liquid crystal display panel of an ECB mode.

<11> The method according to any one of <1> to <9>, wherein the liquid crystal display panel defines a liquid crystal display panel of an OCB mode.

<12> A liquid crystal display panel that is produced in the method for producing the liquid crystal display panel according to any one of <1> to <11>.

### Advantageous Effects of Invention

The method for producing the liquid crystal display panel of the preferred embodiments of the present invention allows enhanced production efficiency of the liquid crystal display panel, and can prevent the liquid crystal molecules controlled by the optical alignment films from having a deviated pretilt direction.

### BRIEF DESCRIPTION OF DRAWINGS

FIG. 1 is an explanatory view showing a schematic configuration of a liquid crystal display panel that is yet to be subjected to an alignment treatment.

FIG. 2 is an explanatory view schematically showing an optical alignment film that develops desired alignment regulation power through light irradiation.

FIG. 3 is an explanatory view schematically showing a step of subjecting optical alignment films formed in the liquid crystal display panel to the alignment treatment.

FIG. 4 is an explanatory view showing the schematic configuration of the liquid crystal display panel that is subjected to the alignment treatment.

FIG. 5 is an explanatory view showing the schematic configuration of the liquid crystal display panel on outer surfaces of which a pair of polarizing plates is attached.

FIG. 6 is an explanatory view schematically showing an orientation of a polarization axis of the polarizing plate attached to a transparent substrate.

FIG. 7 is an explanatory view schematically showing a method for producing a liquid crystal display panel of another preferred embodiment of the present invention.

FIG. 8 is an explanatory view showing a schematic configuration of a liquid crystal display panel of another preferred embodiment of the present invention.

FIG. 9 is an explanatory view schematically showing an optical alignment film that develops desired alignment regulation power through light irradiation.

FIG. 10 is an explanatory view schematically showing a method for producing a liquid crystal display panel, in which alignment films are domain-divided.

FIG. 11 is an explanatory view schematically showing the method for producing the liquid crystal display panel, in which the alignment films are domain-divided.

FIG. 12 is an explanatory view schematically showing another method for producing a liquid crystal display panel, in which alignment films are domain-divided.

FIG. 13 is an explanatory view schematically showing another method for producing a liquid crystal display panel, in which alignment films are domain-divided.

### DESCRIPTION OF EMBODIMENTS

Detailed descriptions of a method for producing a liquid crystal display panel of the present invention, and a liquid crystal display panel produced in the method of the present invention will now be provided with reference to the accompanying drawings.

[First Preferred Embodiment of the Present Invention]

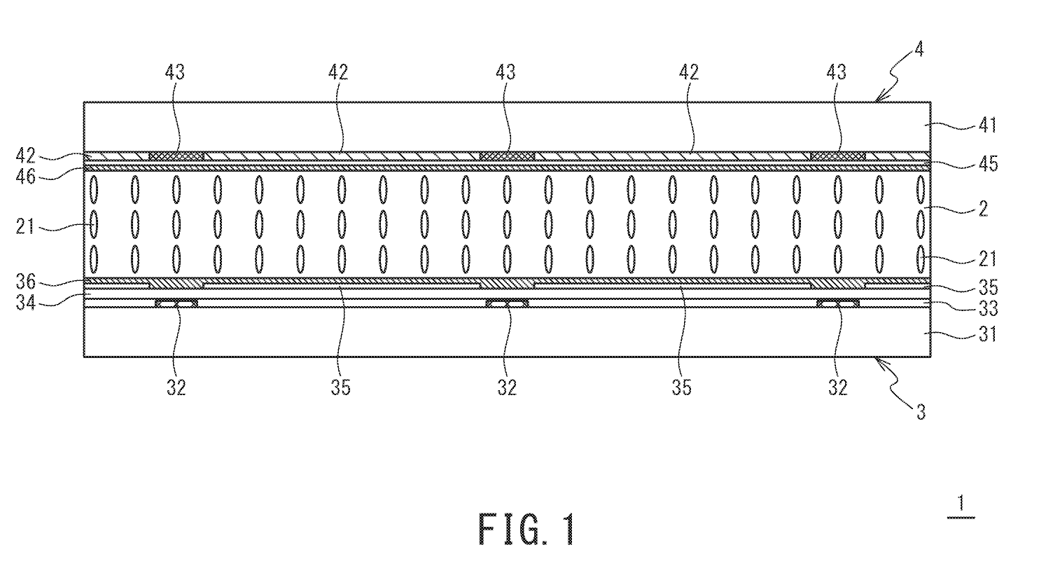

FIG. 1 is an explanatory view showing a schematic configuration of a liquid crystal display panel 1 that is yet to be subjected to an alignment treatment. Shown in FIG. 1 is a schematic partial cross-sectional view of the liquid crystal display panel 1. The liquid crystal display panel 1 is used for a transmissive liquid crystal display device of an active matrix drive type. The liquid crystal display panel 1 includes a liquid crystal layer 2, and a pair of transparent substrates 3 and 4 that are opposed to each other while sandwiching the liquid crystal layer 2 therebetween as shown in FIG. 1.

The liquid crystal layer 2 is of the same kind as a vertical-alignment-type liquid crystal layer, and contains a nematic 1 liquid crystal material (liquid crystal molecules) 21 that have negative dielectric anisotropy. The liquid crystal layer 2 is not a liquid crystal layer containing a polymerizable compound that is used in a PSA (Polymer Sustained Alignment) mode. The liquid crystal molecules 21 in the liquid crystal layer 2 are made from a non-polymerizable compound that is not polymerized by light projected in an alignment treatment. The liquid crystal molecules 21 having a long and thin shape are shown in FIG. 1 and other figures.

The transparent substrate 3 defines a thin film transistor (TFT) substrate that is made of a glass substrate 31 having a flat front and back faces, on which a plurality of thin film transistors (not shown) that define active elements are arranged in a matrix. Further, a plurality of gate bus lines 32 that are parallel to each other, and a plurality of source bus lines (not shown) that are parallel to each other and intersected with the gate bus lines 32 are formed on the glass substrate 31 of the TFT substrate 3.

The TFTs include gate electrodes (not shown) that are formed of a conductive layer of which the gate bus lines 32 are also made, a gate insulating film 33 that covers the gate electrodes, a semiconductor layer (not shown) that is formed on the gate insulating film 33 so as to oppose the gate electrodes, source electrodes (not shown) that are formed of a conductive layer of which the source bus lines are also made, and drain electrodes (not shown). These elements are covered by an interlayer insulating film 34 made of resin.

A plurality of pixel electrodes 35 are formed of an ITO (Indium Tin Oxide) film on the interlayer insulating film 34. The pixel electrodes 35 are each connected to the drain electrodes of the TFTs in contact holes (not shown).

An optical alignment film 36 is formed so as to cover surfaces of the pixel electrodes 35. The optical alignment film 36 is yet to be subjected to an alignment treatment for giving desired alignment regulation power thereto. The optical alignment film 36 will be described in detail later.

The transparent substrate 4 defines a color film (CF) substrate 4 that is made of a glass substrate 41 having a flat front and back faces, on which a plurality of color filter layers 42 are formed. The color filter layers 42 of the CF substrate 4 are arranged in a matrix so as to correspond to the pixel electrodes 35 of the TFT substrate 3. In addition, a light-shielding black matrix 43 is formed on the glass substrate 41 of the CF substrate 4. The black matrix 43 has a lattice pattern so as to section and surround the color filter layers 42 on the glass substrate 41.

A counter electrode (common electrode) 45 is formed so as to cover surfaces of the color filter layers 42 and the black matrix 43. The counter electrode 45 is formed of an ITO (Indium Tin Oxide) film, and a given voltage is placed between the counter electrode 45 and the pixel electrodes 35 on the TFT substrate 3.

An optical alignment film 46 is formed so as to cover a surface of the counter electrode 45. The optical alignment film 46 is yet to be subjected to an alignment treatment for giving desired alignment regulation power thereto, similarly to the optical alignment film 36 of the TFT substrate 3.

The liquid crystal molecules 21 in the liquid crystal layer 2 that are sandwiched by the optical alignment films 36 and 46 that are yet to be subjected to the alignment treatment are aligned in a vertical direction to surfaces of the optical alignment films 36 and 46 as shown in FIG. 1.

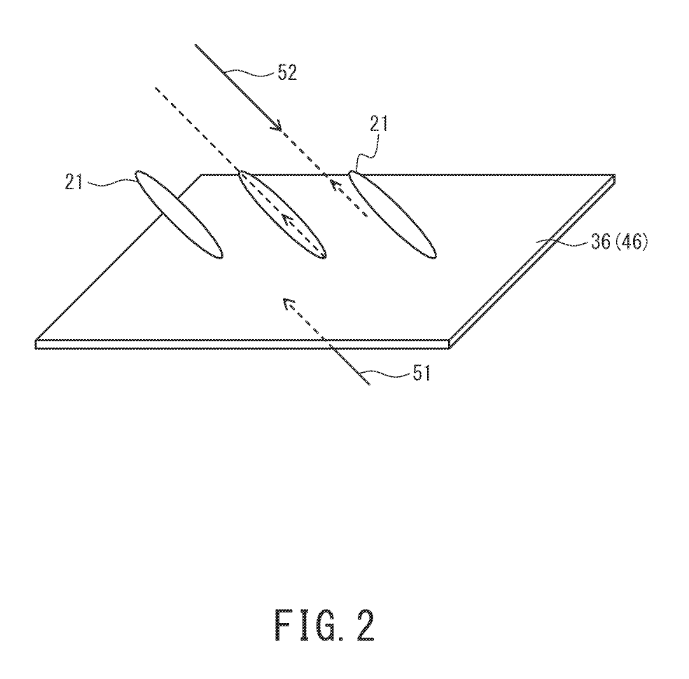

A description of the optical alignment films 36 and 46 is provided with reference to FIG. 2. FIG. 2 is an explanatory view schematically showing the optical alignment film that develops desired alignment regulation power through light irradiation, where ultraviolet linear polarized light 51 is projected from a back surface of the optical alignment film 36, 46. The optical alignment films 36 and 46 are made from a polyimide in which the side chains are substituted with functional groups that cause photodimerization reaction such as a cinnamate or a coumalin (see NPL 1 and PTL 2), and develop the alignment regulation power to tilt the liquid crystal molecules 21 in a direction parallel to the irradiation direction of the light 51. Also when light 52 is projected in an opposite direction to the light 51 from a front surface of the optical alignment film 36, 46, the optical alignment film 36, 46 develops the alignment regulation power to tilt the liquid crystal molecules 21 in the direction parallel to the irradiation direction of the light 52.

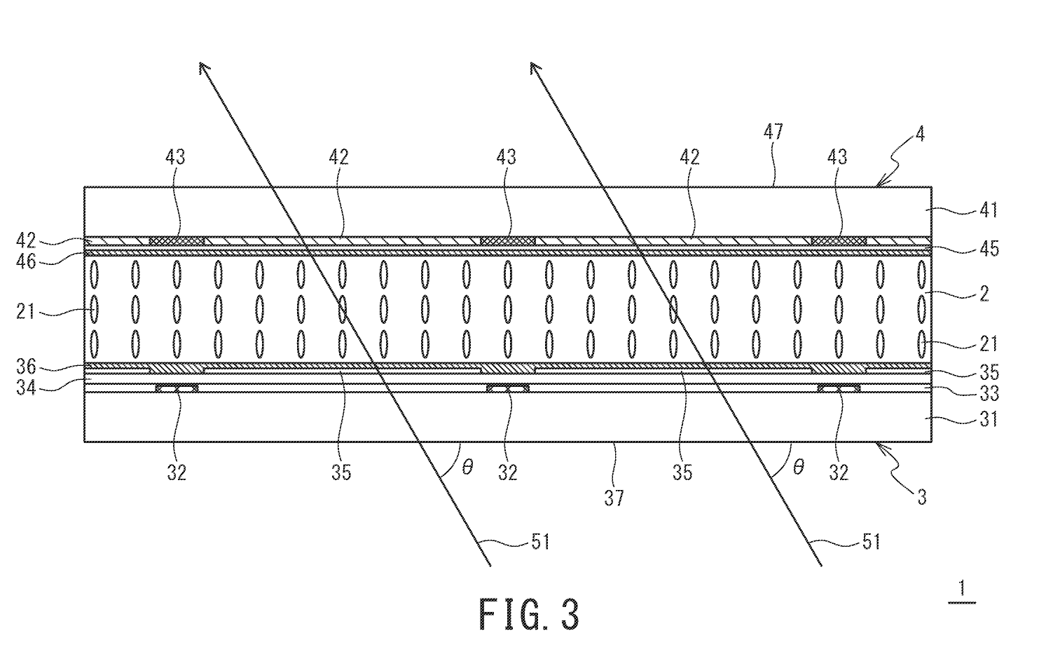

Next, a description of a method for producing the liquid crystal display panel 1 will be provided with reference to FIGS. 1 and 3.

<Bonding Step>

The paired transparent substrates 3 and 4, on which the optical alignment films 36 and 46 yet to be subjected to the alignment treatment are formed respectively, are bonded so as to be opposed to each other while sandwiching the liquid crystal layer 2 therebetween as shown in FIG. 1. The transparent substrates 3 and 4 are bonded so as to be opposed to each other with the use of a sealing agent (not shown). The transparent substrates 3 and 4 are preferably bonded basically in a method for bonding conventional transparent substrates except that the optical alignment films 36 and 46 are yet to be subjected to the alignment treatment.

After the bonding step, the optical alignment film 36 yet to be subjected to the alignment treatment is located on the inner surface of the transparent substrate (TFT substrate) 3, and the optical alignment film 46 yet to be subjected to the alignment treatment is located on the inner surface of the transparent substrate (CF substrate) 4. The optical alignment films 36 and 46 are opposed to each other sandwiching the liquid crystal layer 2 therebetween.

<Alignment Treatment Step>

FIG. 3 is an explanatory view schematically showing a step of subjecting optical alignment films 36 and 46 formed in the liquid crystal display panel 1 to the alignment treatment. The ultraviolet linear polarized light 51 emitted from a predetermined light source (not shown) is projected from an outer surface 37 of the TFT substrate 3, which is bonded with the CF substrate 4 so as to be opposed to each other, toward the outer surface of the CF substrate 4 so as to obliquely traverse the optical alignment films 36 and 46. During this alignment treatment step, no voltage is placed between the pixel electrodes 35 on the TFT substrate 3 and the counter electrode 45 on the CF substrate 4.

The light 51 is projected so as to enter the outer surface 37 of the TFT substrate 3 (i.e., outer surface of the glass substrate 31) at an angle θ. The angle θ is preferably within a range of thirty to sixty degrees. In the present embodiment, the angle θ is set as forty-five degrees. The light 51 is projected evenly onto the entire outer surface 37 of the TFT substrate 3. The projected light 51 obliquely traverses (passes through) the optical alignment film 36 formed on the inner surface of the TFT substrate 3, and the optical alignment film 46 formed on the inner surface of the CF substrate 4. Projecting the light 51 onto the liquid crystal display panel 1 as described above allows the optical alignment films 36 and 46 to be simultaneously subjected to the alignment treatment through single projection of the light 51. Thus, each of the optical alignment films 36 and 46 develops desired alignment regulation power in accordance with the irradiation angle θ of the light 51. The alignment treatment described above allows the optical alignment films 36 and 46 to develop the desired alignment regulation power at opening portions of the pixels of the liquid crystal display panel 1. It is to be noted that even if the gate bus lines 32 and the black matrix 43 and other elements are disposed on the TFT substrate 3 and the CF substrate 4 respectively, the alignment treatment performed on the optical alignment films 36 and 46 at the opening portions of the liquid crystal display panel 1 is not hindered thereby.

The intensity of the light 51 used for the alignment treatment is preferably 10 mJ to 1 J, and more preferably 50 mJ to 1 J.

In another embodiment of the present invention, it is preferable that the optical alignment films 36 and 46 are subjected to the alignment treatment by projecting light from the outer surface 47 of the CF substrate 4 toward the outer surface 37 of the TFT substrate 3, which is opposite to the above-described embodiment of the present invention. However, the color filter layers 42 and the black matrix 43 on the CF substrate 4 are apt to absorb light such as ultraviolet light, so that it is preferable to project the light 51 from the outer surface 37 of the TFT substrate 3 toward the outer surface 47 of the CF substrate 4.

Thus, subjecting the optical alignment films 36 and 46 to the alignment treatment after bonding the pair of transparent substrates 3 and 4 as described above can prevent the liquid crystal molecules 21 in the liquid crystal layer 2 from having a deviated pretilt direction (pretilt angle). In addition, it is unnecessary to perform positional agreement between the optical alignment films 36 and 46, so that the portions of the optical alignment films 36 and 46 that are subjected to the alignment treatment are not deviated from each other. In addition, subjecting the optical alignment films 36 and 46 to the alignment treatment as described above allows enhanced production efficiency of the liquid crystal display panel 1.

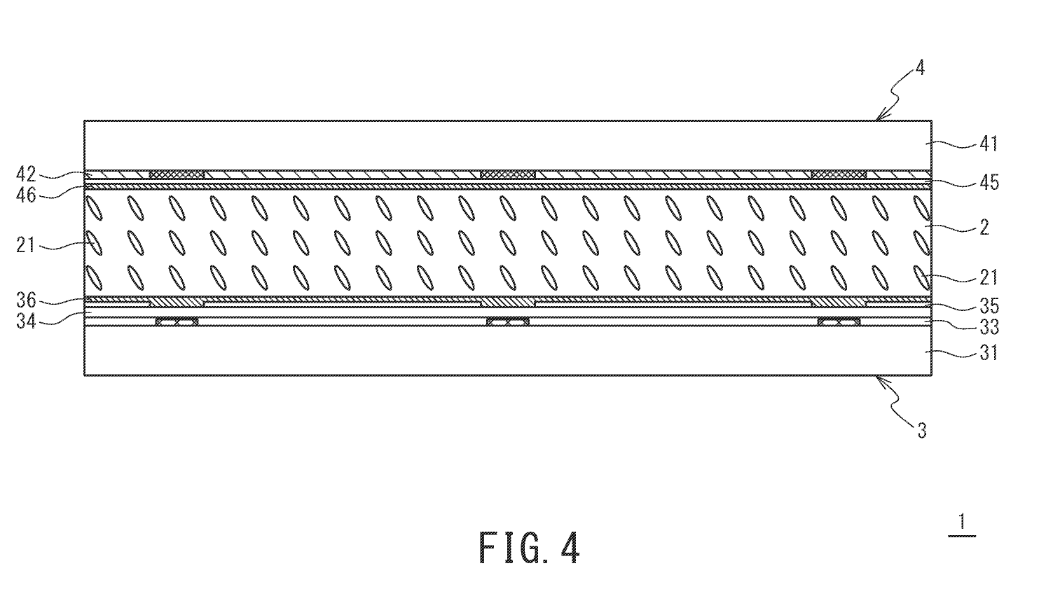

FIG. 4 is an explanatory view showing the schematic configuration of the liquid crystal display panel 1 that is subjected to the alignment treatment. The liquid crystal molecules 21 in the liquid crystal layer 2 sandwiched between the optical alignment films 36 and 46 are tilted uniformly by the alignment regulation power of the optical alignment films 36 and 46 and aligned in a predetermined pretilt direction as shown in FIG. 4. The liquid crystal layer 2 of the liquid crystal display panel 1 is of a so-called ECB (Electrically Controlled Birefringence) mode. The production method of the present embodiment allows the liquid crystal display panel 1 of the ECB mode to be obtained.

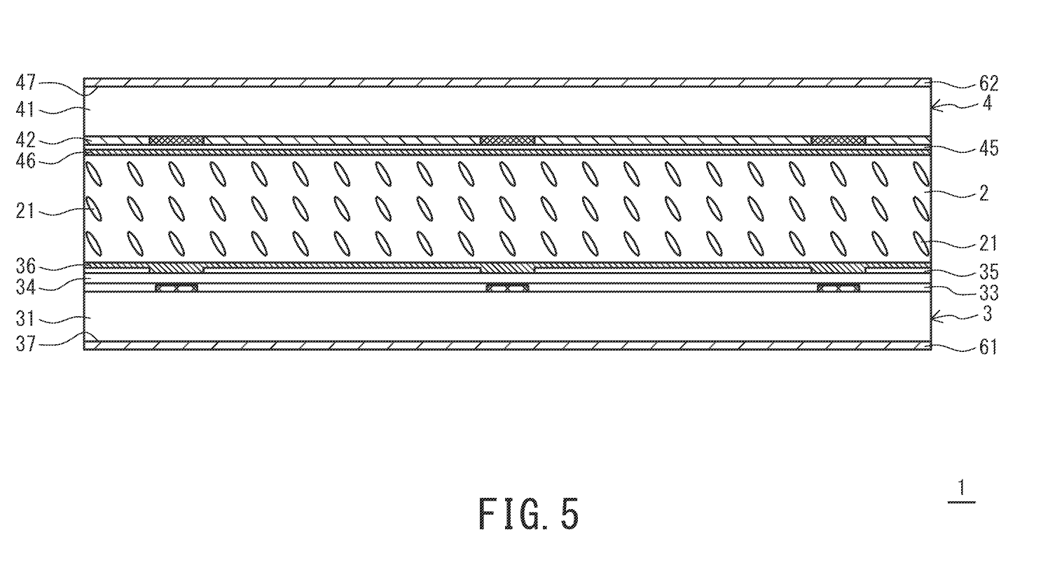

FIG. 5 is an explanatory view showing the schematic configuration of the liquid crystal display panel 1 on the outer surfaces 37 and 47 of which a pair of polarizing plates 61 and 62 is attached. The polarizing plate 61 is attached to the outer surface 37 of the glass substrate 31 of the TFT substrate 3 while the polarizing plate 62 is attached to the outer surface 47 of the glass substrate 41 of the CF substrate 4 as shown in FIG. 5 (attaching step).

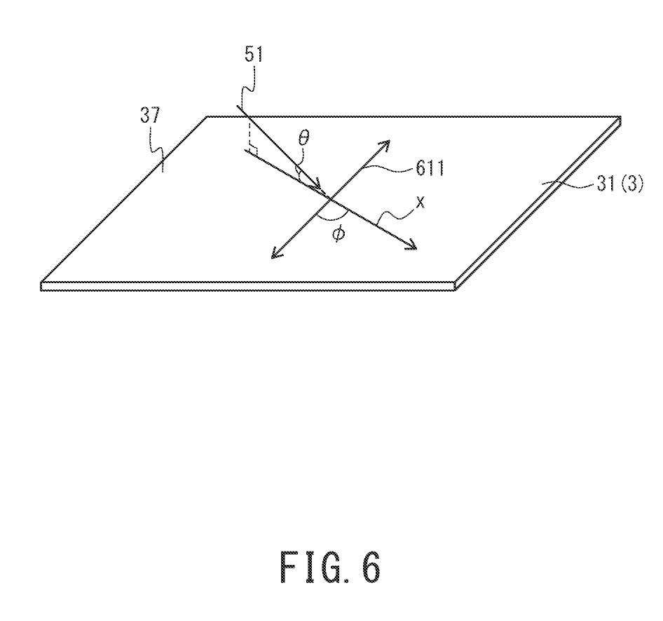

FIG. 6 is an explanatory view schematically showing an orientation of a polarization axis 611 of the polarizing plate attached to the transparent substrate 3. The polarization axis 611 of the polarizing plate 61 (see FIG. 5) is set at an angle φ with respect to an orientation x of the light 51 that is projected at the angle θ with respect to the outer surface 37 of the transparent substrate 3 (glass substrate 31). In the present embodiment, the orientation of the light 51 defines an orientation within a plane surface of the transparent substrate 3 (the liquid crystal display panel 1), and does not contain an elevation component. In the present embodiment, the angle θ is set as forty-five degrees.

The polarizing plate 62 shown in FIG. 5 is attached to the CF substrate 4 such that its polarization axis is perpendicular (crossed Nicols) to the polarization axis 611 of the polarizing plate 61. Similarly to the polarization axis 611, the polarization axis of the polarizing plate 62 is set at the angle φ with respect to the orientation x of the light 51. To be specific, the polarization axes of the polarizing plats 61 and 62 are set so as to be tilted at the angle φ (forty-five degrees) with respect to the orientation x.

Phase plates (not shown) and other constituent elements are preferably provided to the liquid crystal display panel 1 in addition to the polarizing plates 61 and 62.

### Second Preferred Embodiment of the Present Invention

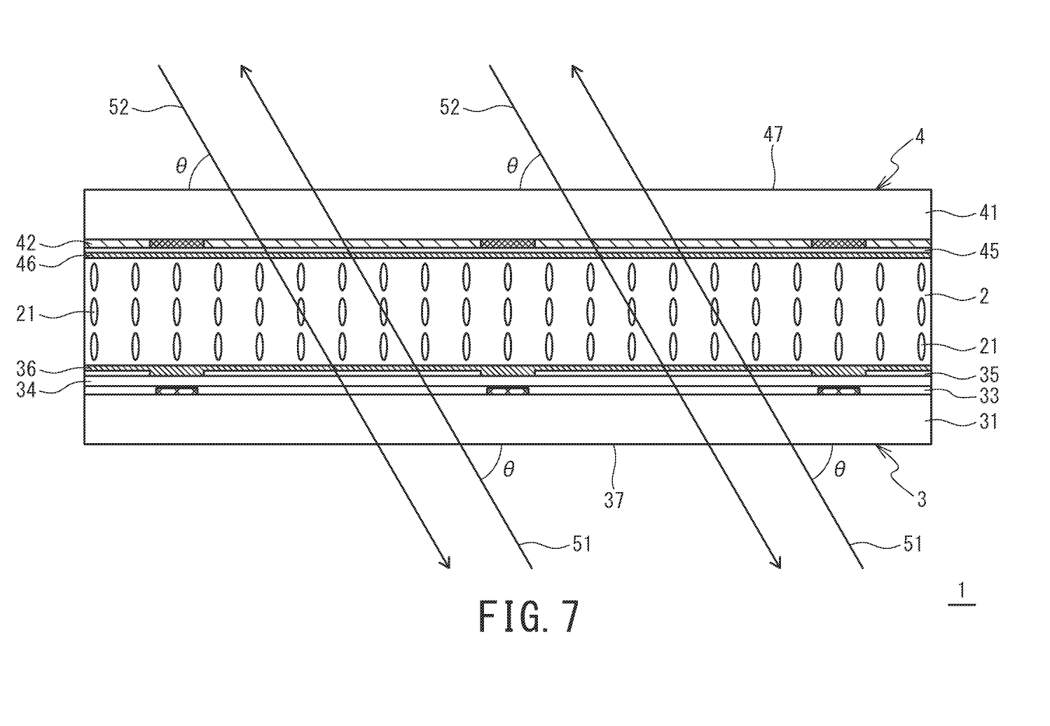

FIG. 7 is an explanatory view schematically showing a method for producing a liquid crystal display panel of another preferred embodiment of the present invention. The configuration of the liquid crystal display panel 1 shown in FIG. 7 is similar to that of the liquid crystal display panel 1 shown in FIGS. 1 and 3. In the method for producing the liquid crystal display panel of the present embodiment, the light 51 and the light 52 are projected simultaneously from the outer surfaces 37 and 47 of the liquid crystal display panel 1, which is different from the production method shown in FIG. 3. The light 51 and the light 52 define ultraviolet linear polarized light, and are projected toward the liquid crystal display panel 1 with the use of predetermined light sources (not shown).

The light 51 is projected onto the outer surface 37 of the glass substrate 31 of the TFT substrate 3 at the angle θ, and the light 52 is projected onto the outer surface 47 of the glass substrate 41 of the CF substrate 4 at the angle θ. The light 51 and the light 52 are parallel to each other while travelling in directions opposite to each other (hereinafter, referred to as being parallel and opposite in direction to each other). The angle θ is preferably within a range of thirty to sixty degrees, which is same as the above-described embodiment. In the present embodiment, the angle θ is set as forty-five degrees. The light 51 and the light 52 are projected evenly onto the entire outer surface 37 and the entire outer surface 47, respectively.

Subjecting the optical alignment films 36 and 46 to the alignment treatments with the use of the light 51 and the light 52 that are parallel and opposite in direction to each other allows the liquid crystal display panel 1 of the ECB mode shown in FIG. 4 to be obtained.

In the present embodiment, it is preferable that the alignment treatments are performed such that the light 51 is first projected onto the outer surface 37 of the TFT substrate 3, and then the light 52 is projected onto the outer surface 47 of the CF substrate 4. It is also preferable that the alignment treatments are performed such that the light 52 is first projected onto the outer surface 47 of the CF substrate 4, and then the light 51 is projected onto the outer surface 37 of the TFT substrate 3.

### Third Preferred Embodiment of the Present Invention

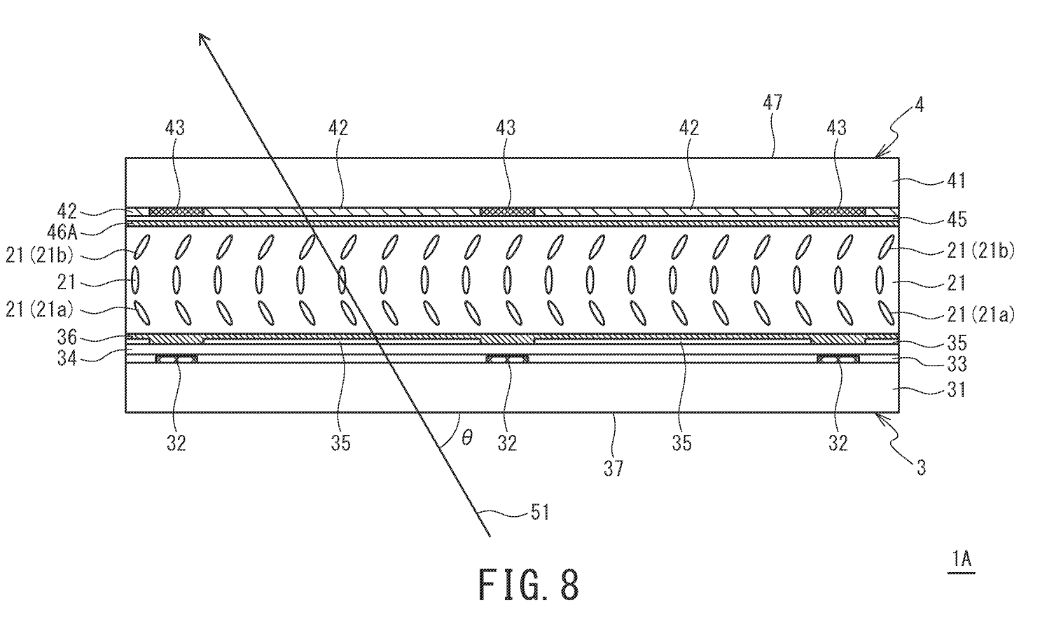

FIG. 8 is an explanatory view showing a schematic configuration of a liquid crystal display panel 1A of another preferred embodiment of the present invention. The basic configuration of the liquid crystal display panel 1A shown in FIG. 8 is similar to that of the liquid crystal display panel 1 shown in FIG. 4; however, an optical alignment film 46A formed on the inner surface of the CF substrate 4 of the liquid crystal display panel 1A is different from the optical alignment film 46 of the liquid crystal display panel 1. The liquid crystal display panel 1A can be produced in a manner similar to the manner for producing the liquid crystal display panel 1 except that the optical alignment film 46A is formed on the CF substrate 4.

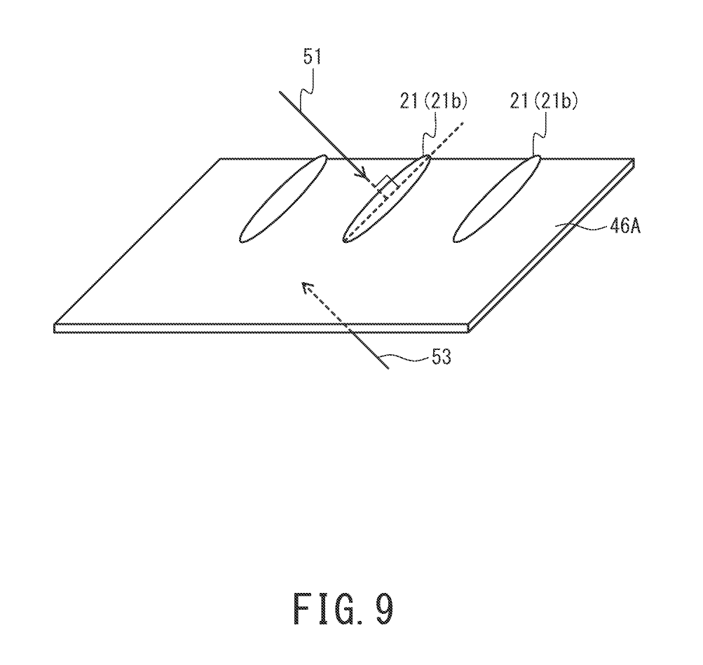

A description of the optical alignment film 46A formed on the CF substrate 4 shown in FIG. 8 is provided with reference to FIG. 9. FIG. 9 is an explanatory view schematically showing the optical alignment film 46A that develops desired alignment regulation power through light irradiation, where the ultraviolet linear polarized light 51 is projected from a front surface of the optical alignment film 46A. The optical alignment film 46A develops the alignment regulation power to tilt the liquid crystal molecules 21 (21b) in a direction perpendicular to the irradiation direction of the light 51. The optical alignment film 46A is made from a known polyimide in which the side chains are substituted with photoreactive functional groups (see NPL 1 and PTL 2). It is to be noted that the optical alignment film 46A develops the alignment regulation power to tilt the liquid crystal molecules 21 (21b) in a direction perpendicular to an irradiation direction of the light 53 also when ultraviolet linear polarized light 53 that is opposite indirection (parallel and opposite in direction) to the light 51 is projected from a back surface of the optical alignment film 46A.

The light 51 is projected onto the liquid crystal display panel 1A, in which the optical alignment film 46A shown in FIG. 9 is formed on the inner surface of the CF substrate 4, from the outer surface 37 of the TFT substrate 3 toward the outer surface 47 of the CF substrate 4 as shown in FIG. 8, whereby the optical alignment films 36 and 46A are subjected to the alignment treatment. The light 51 is projected onto the outer surface 37 of the glass substrate 31 of the TFT substrate 3 at the angle θ (forty-five degrees) . The other irradiation conditions of the light 51 are same as those for alignment treatment of the liquid crystal display panel 1 shown in FIG. 3.

Subjecting the optical alignment films 36 and 46A to the alignment treatment as shown in FIG. 9 allows the optical alignment film 36 to develop the alignment regulation power to tilt the liquid crystal molecules (21a) in a direction parallel to the irradiation direction of the light 51 as shown in FIG. 2, and allows the optical alignment film 46A to develop the alignment regulation power to tilt the liquid crystal molecules 21 (21b) in the direction perpendicular to the irradiation direction of the light 51 as shown in FIG. 9. Thus, the pretilt direction of the liquid crystal molecules 21 in the liquid crystal layer 2, which are close to the optical alignment film 36 formed on the TFT substrate 3, becomes opposite to the pretilt direction of the liquid crystal molecules 21 in the liquid crystal layer 2, which are close to the optical alignment film 46A formed on the CF substrate 4. The liquid crystal molecules 21 in the liquid crystal layer 2 are arranged in arching lines as a whole between the optical alignment films 36 and 46A. That is, the liquid crystal layer 2 of the liquid crystal display panel 1A of the present embodiment that is subjected to the alignment treatment is of a so-called OCB (Optically Compensated Birefringence) mode.

Choosing the optical alignment films 36 and 46A as appropriate as described above allows the liquid crystal display panel 1A of the OCB mode to be obtained.

### Fourth Preferred Embodiment of the Present Invention

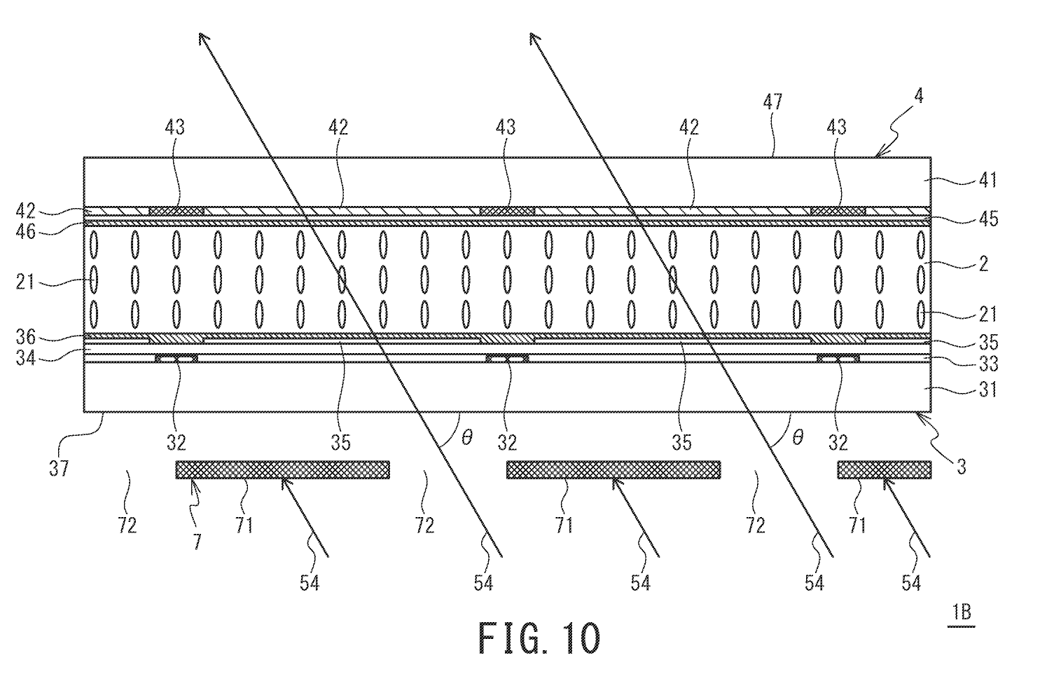

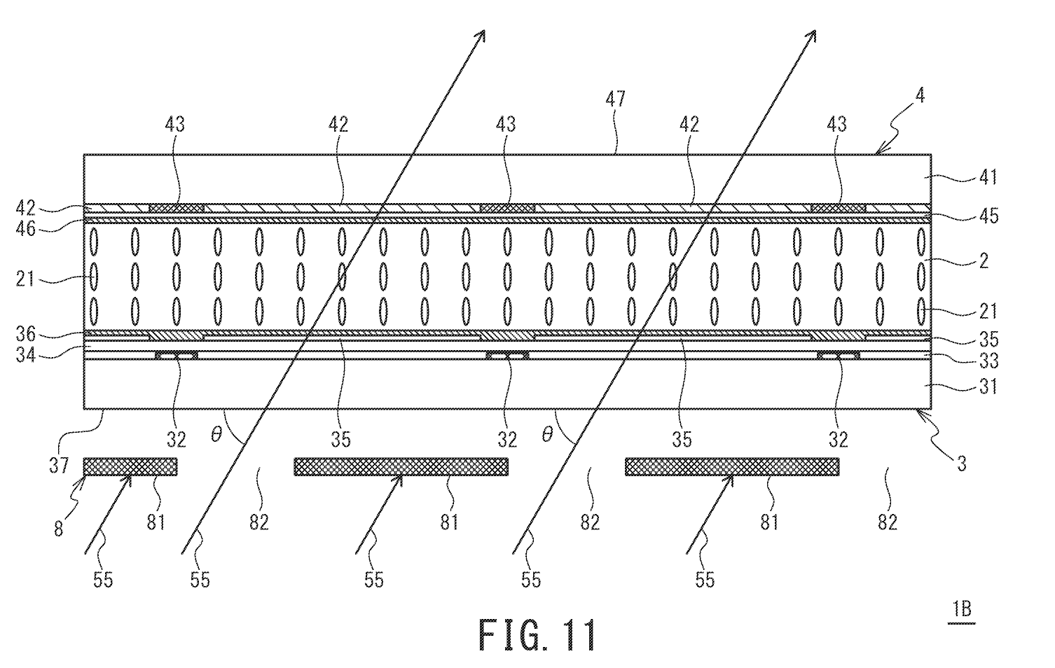

FIGS. 10 and 11 are explanatory views schematically showing a method for producing a liquid crystal display panel 1B, in which the alignment films 36 and 46 are domain-divided. The liquid crystal display panel 1B is subjected to alignment treatments such that the optical alignment films 36 and 46 are irradiated with light 54 and light 55 in different directions. Two kinds of domains that are in accordance with the irradiation directions (not shown) are formed in each of the optical alignment films 36 and 46. The orientations of the alignment regulation power developed in the domains are different from each other, and symmetric. The configuration and the production method of the liquid crystal display panel 1B that is yet to be subjected to the alignment treatments (i.e., the bonding step) are same as those of the liquid crystal display panel 1 shown in FIGS. 1 and 3.

In subjecting the optical alignment films 36 and 46 to the alignment treatments, a first exposure mask 7 is first placed above the outer surface 37 of the transparent substrate (TFT substrate) 3 (below the TFT substrate 3 shown in FIG. 10) so as to cover the outer surface 37 as shown in FIG. 10. The first exposure mask 7 includes a light shielding portion 71 that has a frame shape and is arranged to shield the light 54 projected to the optical alignment films 36 and 46, and a plurality of transmitting portions 72 that define hollow portions surrounded by the frame-shaped light shielding portion 71 and are arranged to transmit the light 54. The shape of each transmitting portion 72 corresponds to the shape of the domains of either one kind to be formed on the optical alignment films 36 and 46.

Next, the light 54 is projected toward the outer surface 37 of the transparent substrate (TFT substrate) 3 via the first exposure mask 7. The light 54 is projected using the light source (not shown) that is used in the first embodiment. An incident angle θ of the light 54 is set as fifty-five degrees. The projected light 54 that passes through the transmitting portions 72 of the first exposure mask 7 travels from the outer surface 37 of the transparent substrate (TFT substrate) 3 toward the outer surface 47 of the transparent substrate (CF substrate) 4 so as to obliquely traverse the optical alignment films 36 and 46. Thus, the domains of the either one kind are formed in the optical alignment films 36 and 46, which develop alignment regulation power in accordance with the radiation direction of the light 54. Meanwhile, the light 54 that hits the light shielding portion 71 of the first exposure mask 7 is shielded thereby. After the irradiation with the light 54 is performed at a given intensity for a given time, the first exposure mask 7 is retired from the position above the transparent substrate (TFT substrate) 3 (below the TFT substrate 3 shown in FIG. 10).

Next, a second exposure mask 8 is then placed above the outer surface 37 of the TFT substrate 3 (below the TFT substrate 3 shown in FIG. 10) as shown in FIG. 11. The second exposure mask 8 includes a light shielding portion 81 that has a frame shape and is arranged to shield the light 55 projected in the direction different from the light 54, and a plurality of transmitting portions 82 that define hollow portions surrounded by the frame-shaped light shielding portion 81 and are arranged to transmit the light 55. The shape of each transmitting portion 82 corresponds to the shape of the domains of the other kind to be formed on the optical alignment films 36 and 46.

Next, the light 55 is projected toward the outer surface 37 of the transparent substrate (TFT substrate) 3 via the second exposure mask 8. The irradiation direction of the light 55 is different from that of the light 54. An orientation of the light 55 is inverse one-hundred-eighty degrees to that of the light 54 at the incident plane (the outer surface 37). An incident angle θ of the light 55 is set as fifty-five degrees. The light 55 is projected using a light source (not shown) that is different from the light source for the light 54. The conditions other than the incident direction (orientation) of the light 55 are set similarly to those of the light 54.

The projected light 55 that passes through the transmitting portions 82 of the second exposure mask 8 travels from the outer surface 37 of the transparent substrate (TFT substrate) 3 toward the outer surface 47 of the transparent substrate (CF substrate) 4 so as to obliquely traverse the optical alignment films 36 and 46. Thus, the domains of the other kind are formed in the optical alignment films 36 and 46, which develop alignment regulation power in accordance with the radiation direction of the light 55. The shapes and the sizes of the light shielding portion 81 and the transmitting portions 82 of the second exposure mask 8 are set such that the light 55 does not pass as much as possible through the domains of the optical alignment films 36 and 46 that have been already subjected to the alignment treatment with the light 54. Meanwhile, the light 55 that hits the light shielding portion 81 of the second exposure mask 8 is shielded thereby. After the irradiation with the light 55 is performed at a given intensity for a given time, the second exposure mask 8 is retired from the position above the transparent substrate (TFT substrate) 3 (below the TFT substrate 3 shown in FIG. 11).

Subjecting the optical alignment films 36 and 46 to the alignment treatments with the light 54 and the light 55 of which the irradiation directions are different from each other using the first exposure mask 7 and the second exposure mask 8 as described above allows the liquid crystal display panel 1B including the domain-divided optical alignment films 36 and 46 to be obtained. This production method can prevent positional deviation between the opposed optical alignment films 36 and 46, and thus can prevent the liquid crystal molecules that are controlled by the optical alignment films 36 and 46 from having a deviated pretilt direction, which allows enhanced production efficiency of the liquid crystal display panel 1B.

### Fifth Preferred Embodiment of the Present Invention

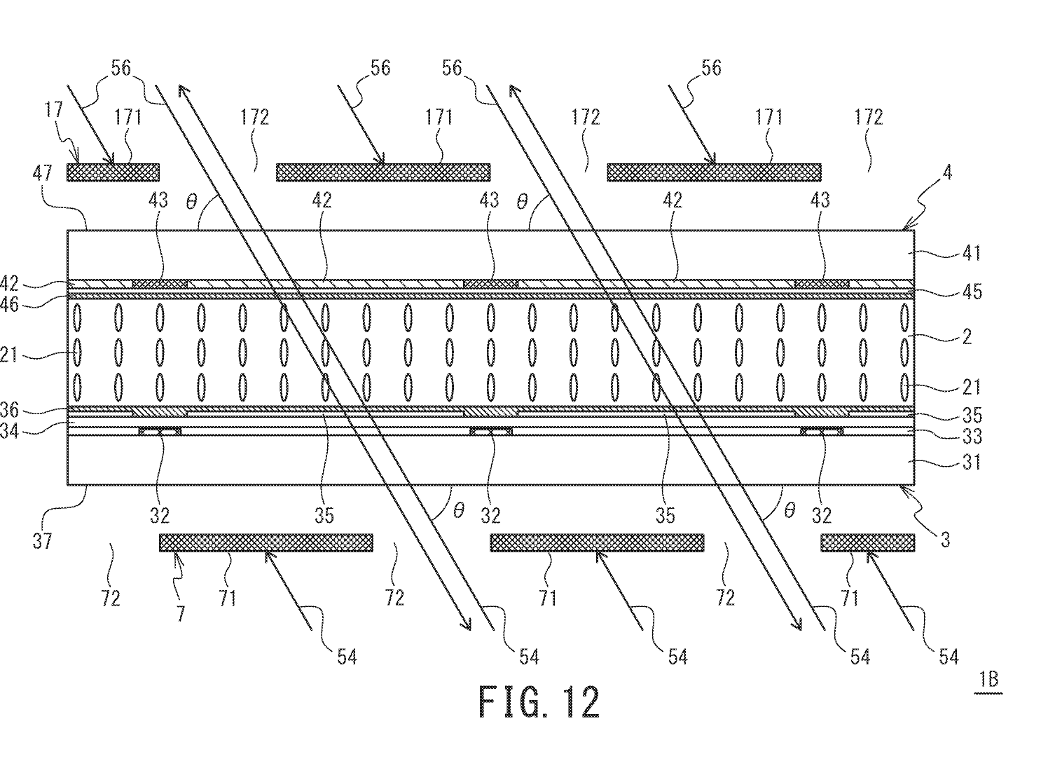

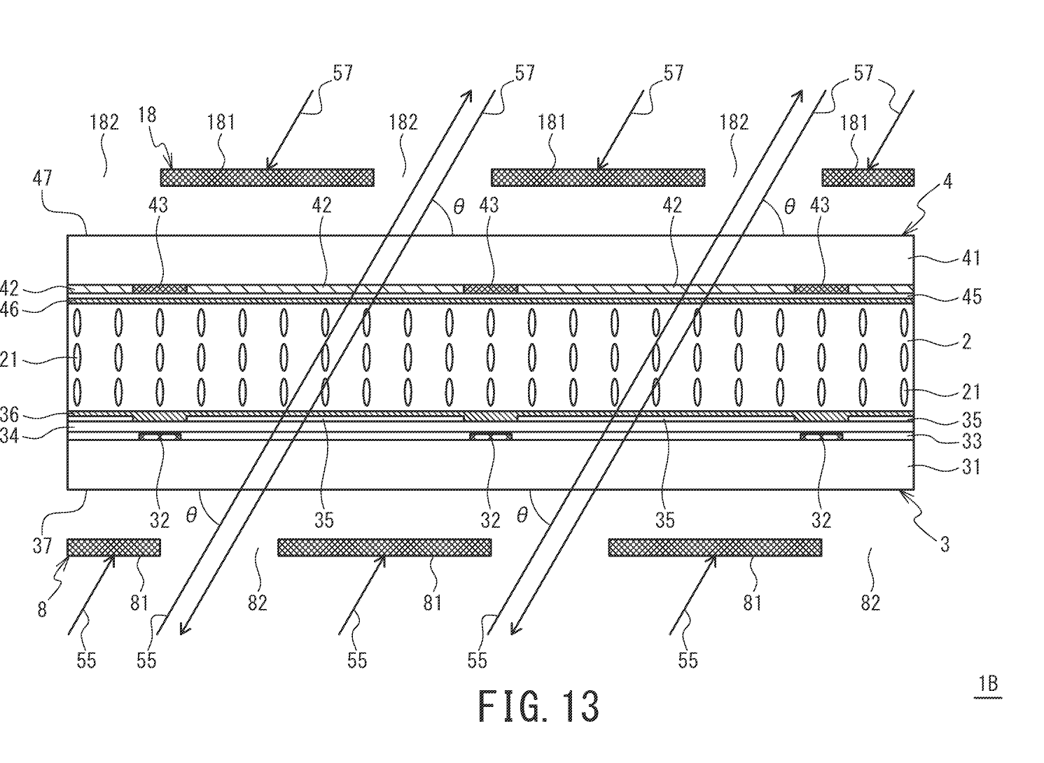

FIGS. 12 and 13 are explanatory views schematically showing another method for producing the liquid crystal display panel 1B, in which the alignment films 36 and 46 are domain-divided. The configuration of the liquid crystal display panel 1B produced in this method is same as that of the liquid crystal display panel 1B of the fourth preferred embodiment shown in FIGS. 10 and 11. The liquid crystal display panel 1B includes the optical alignment films 36 and 46 in each of which two kinds of domains that are in accordance with irradiation directions (not shown) are formed. In the production method of the present embodiment, the alignment treatment is performed such that light is projected in a plurality of directions from the outer surfaces 37 and 47 of the pair of transparent substrates 3 and 4, where the light from the outer surface 37 and the light from the outer surface 47 are parallel and opposite indirection to each other, which is different from the production method of the fourth preferred embodiment.

A first exposure mask 7 for TFT-substrate side is first placed above the outer surface 37 of the TFT substrate 3 (below the TFT substrate 3 shown in FIG. 12) so as to cover the outer surface 37 as shown in FIG. 12. The first exposure mask 7 used in the present embodiment has the same configuration as the one shown in FIG. 10. Then, a first exposure mask 17 for CF-substrate side is placed above the outer surface 47 of the CF substrate (below the CF substrate 4 shown in FIG. 12) so as to cover the outer surface 47. The first exposure mask 17 for CF-substrate side has the same configuration as the first exposure mask 7 for TFT-substrate side, and includes a light shielding portion 171 that has a frame shape and a plurality of transmitting portions 172 that define hollow portions. The shape of each transmitting portion 172, as well as the shape of each transmitting portion 72 of the first exposure mask 7 for TFT-substrate side, corresponds to the shape of the domains of either one kind to be formed on the optical alignment films 36 and 46.

Next, the light 54 is projected toward the outer surface 37 of the TFT substrate 3 via the first exposure mask 7 for TFT-substrate side, and light 56 is projected toward the outer surface 47 of the CF substrate 4 via the first exposure mask 17 for CF-substrate side. Irradiation directions of the light 54 and the light 56 are parallel and opposite to each other. Incident angles θ of the light 54 and the light 56 upon the outer surfaces 37 and 47 are set as fifty-five degrees. The light 54 and the light 56 are projected using different light sources (not shown).

The projected light 54 that passes through the transmitting portions 72 of the first exposure mask 7 for TFT-substrate side travels from the outer surface 37 of the TFT substrate 3 toward the outer surface 47 of the CF substrate 4 so as to obliquely traverse the optical alignment films 36 and 46. The projected light 56 that passes through the transmitting portions 172 of the first exposure mask 17 for CF-substrate side travels from the outer surface 47 of the CF substrate 4 toward the outer surface 37 of the TFT substrate 3 so as to obliquely traverse the optical alignment films 46 and 36. Thus, the projection of the light 54 and the light 56 onto the optical alignment films 36 and 46 forms the domains in the optical alignment films 36 and 46, which develop alignment regulation power in accordance with the radiation directions of the light 54 and the light 56.

Further, the first exposure masks 7 and 17 are replaced with exposure masks 8 and 18 as shown in FIG. 13, and the light 55 and light 57, which are parallel and opposite in direction to each other, are projected toward the outer surfaces 37 and 47 in directions different from the light 54 and the light 56. The exposure mask 8 defines a second exposure mask 8 for TFT-substrate side that is placed above the outer surface 37 of the TFT substrate 3 (below the TFT substrate 3 shown in FIG. 13) so as to cover the outer surface 37, and has the same configuration as the exposure mask 8 shown in FIG. 11. The exposure mask 18 defines a second exposure mask 18 for CF-substrate side that is placed above the outer surface 47 of the CF substrate 4 (below the CF substrate 4 shown in FIG. 13) so as to cover the outer surface 47. The second exposure mask 18 for CF-substrate side has the same configuration as the second exposure mask 8 for TFT-substrate side and includes a light shielding portion 181 that has a frame shape and a plurality of transmitting portions 182 that define hollow portions. The shape of each transmitting portion 182, as well as the shape of each transmitting portion 82 of the second exposure mask 8 for TFT-substrate side, corresponds to the shape of the domains of the other kind to be formed on the optical alignment films 36 and 46.

The light 55 is projected toward the outer surface 37 of the TFT substrate 3 via the second exposure mask 8 for TFT-substrate side, and the light 57 is projected toward the outer surface 47 of the CF substrate 4 via the second exposure mask 18 for CF-substrate side. Irradiation directions of the light 55 and the light 57 are parallel and opposite to each other. An orientation of the light 55 shown in FIG. 13 is inverse one-hundred-eighty degrees to that of the light 54 shown in FIG. 12 at the incident plane (the outer surface 37). Similarly, an orientation of the light 57 shown in FIG. 13 is inverse one-hundred-eighty degrees to that of the light 56 shown in FIG. 12 at the incident plane (the outer surface 47).

The projected light 55 that passes through the transmitting portions 82 of the second exposure mask 8 for TFT-substrate side travels from the outer surface 37 of the TFT substrate 3 toward the outer surface 47 of the CF substrate 4 so as to obliquely traverse the optical alignment films 36 and 46. The projected light 57 that passes through the transmitting portions 182 of the second exposure mask 18 for CF-substrate side travels from the outer surface 47 of the CF substrate 4 toward the outer surface 37 of the TFT substrate 3 so as to obliquely traverse the optical alignment films 46 and 36. Thus, the projection of the light 55 and the light 57 onto the optical alignment films 36 and 46 forms the domains in the optical alignment films 36 and 46, which develop alignment regulation power in accordance with the radiation directions of the light 55 and the light 57.

Thus, it is preferable to domain-divide the optical alignment films 36 and 46 by projecting the light and the light in the plurality of directions, which are parallel and opposite in direction, from both the sides of the pair of transparent substrates 3 and 4.

The foregoing description of the preferred embodiments of the method for producing the liquid crystal display panel, and the liquid crystal display panel obtained in the production method has been presented for purposes of illustration and description with reference to the first to fifth preferred embodiments; however, it is not intended to limit the present invention to the embodiments, and modifications and variations are possible as long as they do not deviate from the principles of the present invention.

For example, described above in the preferred embodiments is the configuration that the ultraviolet linear polarized light is used in the alignment treatment; however, the present invention is not limited to this configuration. It is also preferable to use unpolarized light (ultraviolet light) in the alignment treatment depending on the kind of optical alignment films that are chosen to use.

1. A method for producing a liquid crystal display panel comprising a pair of transparent substrates being opposed to each other, a liquid crystal layer that contains liquid crystal molecules and is sandwiched between the transparent substrates, and optical alignment films for aligning the liquid crystal molecules, the optical alignment films being formed on inner surfaces of the transparent substrates and subjected to an alignment treatment through light irradiation, the method comprising:
the step of bonding the transparent substrates to each other while sandwiching the liquid crystal layer therebetween, where the optical alignment films that are yet to be subjected to the alignment treatment are each formed on the transparent substrates; and
the step of subjecting the optical alignment films to the alignment treatment where the light is projected from an outer surface of either one of the bonded transparent substrates toward an outer surface of the other transparent substrate.

2. The method according to claim 1, wherein in the alignment treatment step, an angle of the light that is projected onto the outer surface of the either one transparent substrate is thirty to sixty degrees.

3. The method according to claim 1, wherein in the alignment treatment step, the light is projected in a plurality of directions from the outer surface of the either one transparent substrate toward the outer surface of the other transparent substrate via exposure masks each corresponding to the directions, the exposure masks being disposed above the outer surface of the either one transparent substrate, and thereby the optical alignment films are domain-divided by the light projected in the plurality of directions.

4. The method according to claim 1, wherein one of the paired transparent substrates comprises a thin film transistor substrate comprising a plurality of thin film transistors arranged in a matrix, and the other transparent substrate comprises a color filter substrate comprising a plurality of color filters arranged in a matrix, and in the alignment treatment step, the light is projected from an outer surface of the thin film transistor substrate toward an outer surface of the color filter substrate.

5. The method according to claim 1, wherein the method further comprises the step of each attaching polarizing plates to the outer surfaces of the paired transparent substrates, where polarization axes of the polarizing plates are tilted at about forty-five degrees to an orientation of the projected light.

6. A method for producing a liquid crystal display panel comprising a pair of transparent substrates being opposed to each other, a liquid crystal layer that contains liquid crystal molecules and is sandwiched between the transparent substrates, and optical alignment films for aligning the liquid crystal molecules, the optical alignment films being formed on inner surfaces of the transparent substrates and subjected to alignment treatments through light irradiation, the method comprising:
the step of bonding the transparent substrates to each other while sandwiching the liquid crystal layer therebetween, where the optical alignment films that are yet to be subjected to the alignment treatments are each formed on the transparent substrates; and
the step of subjecting the optical alignment films to the alignment treatments where the light is projected from an outer surface of one of the bonded transparent substrates toward an outer surface of the other transparent substrate, and the light is projected from the outer surface of the other transparent substrate toward the outer surface of the one transparent substrate, the light projected from the outer surface of the one transparent substrate toward the outer surface of the other transparent substrate being parallel and opposite in direction to the light projected from the outer surface of the other transparent substrate toward the outer surface of the one transparent substrate.

7. The method according to claim 6, wherein in the alignment treatment step, angles of the light and the light that are parallel and opposite in direction to each other and projected onto the outer surfaces of the paired transparent substrates are thirty to sixty degrees.

8. The method according to claim 6, wherein in the alignment treatment step, the light and the light that are parallel and opposite in direction to each other are projected in a plurality of directions from the outer surface of the one transparent substrate toward the outer surface of the other transparent substrate and from the outer surface of the other transparent substrate toward the outer surface of the one transparent substrate via exposure masks corresponding to the directions, the exposure masks being disposed above the outer surface of the one transparent substrate and above the outer surface of the other transparent substrate, and thereby the optical alignment films are domain-divided by the light and the light projected in the plurality of directions.

9. The method according to claim 6, wherein the method further comprises the step of each attaching polarizing plates to the outer surfaces of the paired transparent substrates, where polarization axes of the polarizing plates are tilted at about 45 degrees to orientations of the projected light and light.

10. The method according to claim 1, wherein the liquid crystal display panel comprises a liquid crystal display panel of an ECB mode.

11. The method according to claim 1, wherein the liquid crystal display panel comprises a liquid crystal display panel of an OCB mode.

12. A liquid crystal display panel that is produced in the method for producing the liquid crystal display panel according to claim 1.
